(19) United States
(12) Patent Application Publication
(10) Pub. No.: US 2012/0154014 A1
(43) Pub. Date: Jun. 21, 2012

(54) LEVEL SHIFT CIRCUIT AND SWITCHING POWER SUPPLY DEVICE

(75) Inventor: Heisuke NAKASHIMA, Tokyo (JP)

(73) Assignee: MITSUMI ELECTRIC CO., LTD, Tama-shi (JP)

(21) Appl. No.: 13/331,087

(22) Filed: Dec. 20, 2011

(30) Foreign Application Priority Data
Dec. 21, 2010 (JP) 2010-284005

(51) Int. Cl. H03L 5/00

(52) U.S. Cl. 327/333

(57) ABSTRACT

A level shift circuit includes a level changing unit which includes first and second MOS transistors connected in series between a first power supply voltage terminal and a grounding point, and receives a signal having a first amplitude which varies between a lower second voltage and a ground potential to convert the signal to a signal having a second amplitude, and an output stage which includes first and second MOS transistors connected in series between the first power supply voltage terminal and a third voltage terminal to which a third voltage lower than the first power supply voltage and higher than the ground potential is supplied, and which stage is connected to an output node of the level changing unit. A first MOS transistor is connected in series between the first MOS transistor and the second MOS transistor of the level changing unit.

### BACKGROUND OF THE INVENTION

1. Field of the Invention

The present invention relates to a level shift circuit having a high (increased) withstand voltage, and for example, to a level shift circuit suitable for being used in a drive circuit which turns on or off a switching element constituting a switching power supply device.

2. Description of Related Art

There is a DC-DC converter of a switching-regulator type, as a circuit which converts a direct-current (DC) input voltage to output a direct-current (DC) voltage having a different potential. The DC-DC converter described above includes a DC-DC converter equipped with: a drive switching element which applies a DC voltage supplied from a DC power supply such as a battery to an inductor (coil), whereby an electric current is flown so that energy is accumulated in the coil; a rectifying element which rectifies the current in the coil during an energy release period during when the drive switching element is turned off; and a control circuit which controls to turn on or off the drive switching element.

Conventionally, the DC-DC converter of the switching-regulator type uses a P-channel Metal-Oxide-Semiconductor Field-Effect Transistor (MOSFET) (insulated gate field effect transistor), or an N-channel MOSFET, as the drive switching element for flowing the current through the inductor. In the case of using the P-channel MOS transistor as the drive switching element, the size of the element increases, since the P-channel MOS transistor has a driving force smaller than that of the N-channel MOS transistor having the same size. When the P-channel MOS transistor is incorporated into a semiconductor chip together with the control circuit for driving the element in order to form a semiconductor integrated circuit, there arise a problem that the chip size is increased.

On the other hand, in the case of using the N-channel MOS transistor as the drive switching element, when the N-channel MOS transistor is driven with a signal having an amplitude same as that of a gate drive signal for the P-channel MOS transistor, an output voltage is reduced by an amount of a threshold voltage. In view of this, a level shift circuit and a bootstrap circuit are provided at the last stage of the circuit which drives the switching element in order to increase the gate voltage of the N-channel MOS transistor.

FIG. 5 illustrates an example of a conventional level shift circuit. In the level shift circuit of FIG. 5, a power supply voltage of an inverter of an input stage 21 is defined as Vdd1-GND, a power supply voltage of a latch circuit 22 provided at the next stage of the inverter is defined as Vdd2-GND (Vdd2>Vdd1), and a power supply voltage of an inverter of an output stage 23 is defined as Vdd2-GND, whereby a signal having an amplitude of Vdd1-GND is level-shifted to a signal having an amplitude of Vdd2-GND, and the resultant is output. In the level shift circuit used in the circuit for driving the switching element of the DC-DC converter, a power supply voltage (ground potential) at the low side of the inverter in the output stage 23 becomes a floating ground FGND whose potential varies depending on an operation state.

In the level shift circuit illustrated in FIG. 5, the voltage of Vdd2 to GND is applied to the gate terminals of the MOS transistors Mp1 to Mp3 and Mn3, which constitute the latch circuit 22 and the output stage 23. When the power supply voltage Vdd2 is higher than the withstand voltage of the P-channel MOS transistor, the element might be broken. In order to avoid the problem described above, an element formed by increasing more a thickness of a gate oxide film than usual so as to have a high withstand voltage may be used as the transistors Mp1 to Mp3 and Mn3.

However, in a production process of a semiconductor integrated circuit having both a high withstand voltage transistor and a normal withstand voltage transistor, two gate oxide films each having a different thickness have to be formed, which might entail a problem that the number of masks to be used and the number of processes increase. This might entail a cost increase. Moreover, an existing production process may not have a process for a high withstand voltage MOS transistor. When such existing production process has to be used, there is a problem that the level shift circuit itself cannot be mounted.

The invention has been proposed (for example, Japanese Patent Application Laid-Open Publication No. 7-074616) in which a transistor for reducing a voltage to be applied is connected between a P-channel MOS transistor and an N-channel MOS transistor in order to increase the withstand voltage. In this regard, however, the present invention has different preconditions and different means to solve the problem from those of the invention described in Japanese Patent Application Laid-Open Publication No. 7-074616.

### SUMMARY OF THE INVENTION

The present invention is accomplished in view of the above-mentioned problem, and the object of the present invention is to provide a technique capable of achieving a level shift circuit having a high (increased) withstand voltage without using a process for increasing a withstand voltage.

In order to achieve the above object, according to a first aspect of the present invention, there is provided a level shift circuit including: a level changing unit which includes a first conductive type MOS transistor and a second conductive type MOS transistor connected to each other in series between a first power supply voltage terminal to which a first power supply voltage is applied and a grounding point, and which unit receives a signal having a first amplitude which varies between a second voltage lower than the first power supply voltage and a ground potential to convert the received signal to a signal having a second amplitude with the first power supply voltage being defined as a reference; and an output stage which includes a first conductive type MOS transistor and a second conductive type MOS transistor connected to each other in series between the first power supply voltage terminal and a third voltage terminal to which a third voltage lower than the first power supply voltage and higher than the ground potential is supplied, and which stage is connected to an output node of the level changing unit, wherein a first conductive type MOS transistor whose gate terminal is connected to the third voltage terminal is connected in series between the first conductive type MOS transistor and the second conductive type MOS transistor of the level changing unit.

### BRIEF DESCRIPTION OF THE DRAWINGS

The present invention will become more fully understood from the detailed description given hereinbelow and the appended drawings which are given by way of illustration only, and thus are not intended as a definition of the limits of the present invention, and wherein:

FIG. 1 is a circuit diagram illustrating a schematic structure of a DC-DC converter of a switching-regulator type in which a level shift circuit according to the present invention is suitably used;

FIG. 2 is a circuit diagram illustrating a level shift circuit according to a first embodiment of the present invention;

FIG. 3 is an explanatory diagram illustrating a potential change in the level shift circuit according to the first embodiment;

FIG. 4 is a circuit diagram illustrating a level shift circuit according to a second embodiment of the present invention; and

FIG. 5 is a circuit diagram illustrating an example of a conventional level shift circuit.

### DETAILED DESCRIPTION OF THE INVENTION

Hereinafter, preferred embodiments of the present invention will be described below with reference to the accompanying drawings.

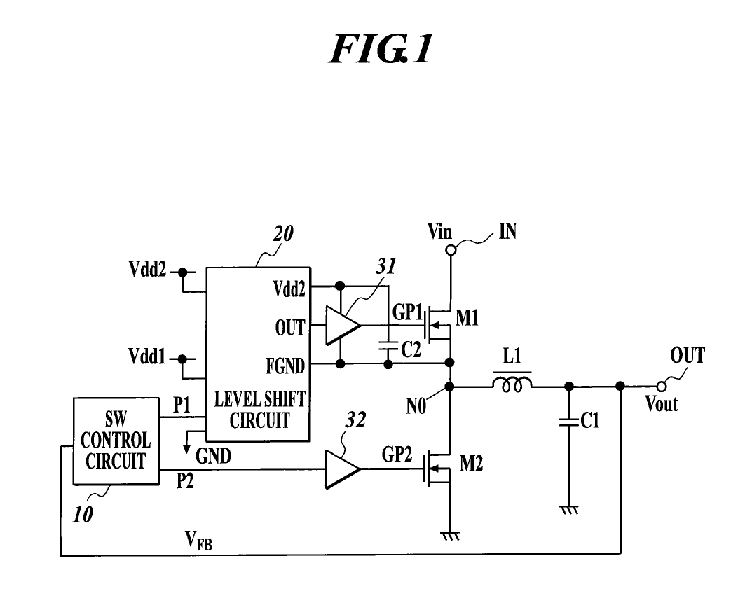

FIG. 1 illustrates a schematic structure of a DC-DC converter of a switching-regulator type in which a level shift circuit according to the present invention is suitably used.

The DC-DC converter according to the present embodiment includes: a coil L1 serving as an inductor; a high-side drive switching element M1 which is connected between a voltage input terminal IN to which a direct-current (DC) input voltage Vin is applied and one of terminals of the coil L1 for flowing a drive current toward the coil L1; a low-side rectification switching element M2 which is connected between the one terminal of the coil L1 and a grounding point; and a smoothing capacitor C1 which is connected to the other terminal (output terminal OUT) of the coil L1 and the grounding point. In the DC-DC converter according to the present embodiment, the drive switching element M1 and the rectification switching element M2 are composed of N-channel MOS transistors.

The DC-DC converter according to the present embodiment also includes: a switching control circuit 10 which generates control signals P1 and P2 for controlling the switching elements M1 and M2 to be turned on or off; a level shift circuit 20 which level-shifts the control signal P1 for turning on or off the high-side element, out of the control signals generated by the switching control circuit 10; a driver 31 which receives the level-shifted signal to generate and output a gate drive signal GP1 for the switching element M1; and a driver 32 which receives the control signal P2 for turning on or off the low-side element, out of the control signals generated by the switching control circuit 10, to generate and output a gate drive signal GP2 for the switching element M2.

Moreover, a capacitor C2 is connected between power supply voltage terminals of the driver 31. With this structure, when a potential of a floating node N0 to which the coil L1 is connected varies, the power supply voltage Vdd2 of the driver 31 changes with this variation, whereby a voltage with a potential difference not less than a predetermined potential difference (e.g. 5 V) is not applied to the driver 31.

Although not particularly limited, the switching control circuit 10, the level shift circuit 20, the drivers 31 and 32, and the switching elements M1 and M2, out of the circuits and elements constituting the DC-DC converter, can be configured as a semiconductor integrated circuit (power supply control IC) formed on a semiconductor chip, and the coil L1 and the capacitor C1 can be configured to be connected to an external terminal which is provided to the IC, as an external element.

In the DC-DC converter in the present embodiment, the control circuit 10 generates the control signals P1 and P2 for turning on or off the switching elements M1 and M2 in a complementary manner. In a steady state, when the drive switching element M1 is turned on, the DC input voltage Vin is applied to the coil L1, whereby the electric current toward the output terminal OUT flows, which charges the smoothing capacitor C1. When the drive switching element M1 is turned off, the rectification switching element M2 is turned on instead, wherein the electric current flows through the coil L1 via the rectification switching element M2 which is turned on.

In a pulse frequency modulation (PFM) control system, the switching control circuit 10 receives a feedback voltage VFB from the output side, makes the pulse width of the drive pulse GP1 constant, the pulse being input to the control terminal (gate terminal) of the switching element M1, and controls the switching frequency according to the output voltage, whereby a DC output voltage Vout of a predetermined potential, which is obtained by decreasing the DC input voltage Vin, is generated.

Furthermore, in a pulse width modulation (PWM) control system, the switching control circuit 10 receives the feedback voltage VFB from the output side, controls the pulse width of the drive pulse GP1 having a constant frequency, which is input to the control terminal (gate terminal) of the switching element M1, according to the output voltage, whereby a DC output voltage Vout having a predetermined potential, which is obtained by decreasing the DC input voltage Vin, is generated.

In the DC-DC converter of FIG. 1, the output voltage Vout is directly input to the switching control circuit 10. However, a configuration where a series resistance is connected in series between the output terminal OUT and the grounding point and divides the output voltage Vout in accordance with a resistance ratio, and the voltage obtained by the division with the resistance is input to the switching control circuit 10 as the feedback voltage VFB may be adopted. In the PFM control system, the switching control circuit 10 is configured to include a comparator which compares the feedback voltage VFB with a predetermined reference voltage to generate a PFM pulse, while in the PWM control system, the switching control circuit 10 is configured to include an error amplifier which generates a voltage which is in proportion to the potential difference between the feedback voltage VFB and a reference voltage, a waveform shaping circuit which generates a triangular waveform having a predetermined frequency, and a comparator which compares the output from the error amplifier with the triangular waveform to generate the PWM pulse.

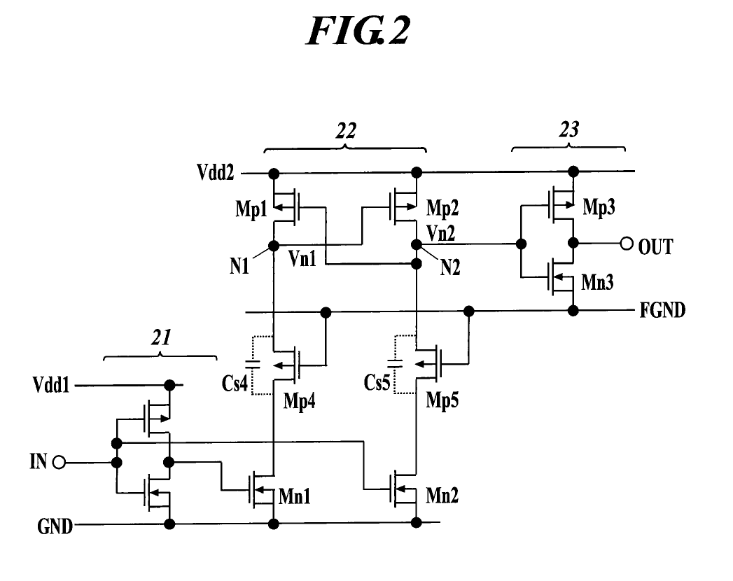

FIG. 2 illustrates the level shift circuit according to the first embodiment of the present invention.

The level shift circuit according to the present embodiment includes: an input stage 21 which is composed of a complementary metal oxide semiconductor (CMOS) inverter; a latch circuit 22 which is provided in a subsequent stage to the inverter; and an output stage 23 which is composed of a CMOS inverter. The power supply voltage of the CMOS inverter 21 in the input stage is defined as Vdd1-GND, the power supply voltage of the latch circuit 22 subsequent to the inverter 21 is defined as Vdd2-GND (Vdd2>Vdd1), and the power supply voltage of the CMOS inverter in the output stage 23 is defined as Vdd2-FGND, whereby a signal having an amplitude of Vdd1-GND is level-shifted to a signal having an amplitude of Vdd2-FGND to be output.

In the level shift circuit to be used in the circuit for driving the high-side switching element M1 of the DC-DC converter having the configuration as illustrated in FIG. 1, the potential of the node N0 to which the coil is connected varies. Therefore, the power supply voltage (ground potential) at the low side of the CMOS inverter in the output stage 23 becomes the floating ground FGND whose potential varies according to the operation state.

The latch circuit 22 in the level shift circuit according to the present embodiment includes P-channel MOS transistors Mp1 and Mp4 and an N-channel MOS transistor Mn1, which are connected in series between the power supply voltage terminal to which the power supply voltage Vdd2 is supplied and the grounding point GND, and P-channel MOS transistors Mp2 and Mp5 and an N-channel MOS transistor Mn2, which are connected in series between the power supply voltage terminal and the grounding point GND. A gate terminal of the MOS transistor Mp2 is connected to a drain terminal of the MOS transistor Mp1, while a gate terminal of the MOS transistor Mp1 is connected to a drain terminal of the MOS transistor Mp2.

The P-channel MOS transistor Mp1 and the N-channel MOS transistor Mn1 which are connected in a serial form, and the P-channel MOS transistor Mp2 and the N-channel MOS transistor Mn2 which are connected in a serial form, constitute CMOS inverters respectively. An output node of each of the two CMOS inverters is cross-linked to a gate terminal of the P-channel MOS transistor of the other CMOS inverter, whereby it is operated as a flip-flop latch circuit.

The gate terminal of the P-channel MOS transistor Mp4 which is connected between the P-channel MOS transistor Mp1 and the N-channel MOS transistor Mn1, and the gate terminal of the P-channel MOS transistor Mp5 which is connected between the P-channel MOS transistor Mp2 and the N-channel MOS transistor Mn2, are connected to the floating ground FGND.

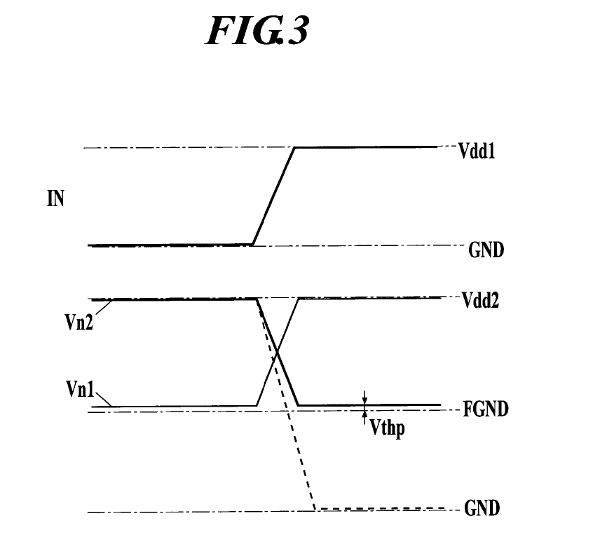

The operation of the level shift circuit illustrated in FIG. 2 thus configured will next be described with reference to FIG. 3.

When considering a case that an input signal IN to the level shift circuit is low level (GND), since the N-channel MOS transistor Mn1 is in on-state and the Mn2 is in off-state, the potential Vn1 of the connection node N1 of the Mp1 and the Mp4 is lower than the power supply voltage Vdd2, whereby the P-channel MOS transistor Mp2 is turned on and the potential Vn2 of the connection node N2 of the Mp2 and the Mp5 has a high level (Vdd2).

When the input signal IN changes from the low level (GND) to the high level (Vdd1) as illustrated in FIG. 3, the N-channel MOS transistor Mn1 is changed from the on-state to the off-state, while the Mn2 is changed from the off-state to the on-state. Thereupon, the potential Vn2 of the node N2 starts to decrease from the high level (Vdd2) to the low level (GND) (the potential Vn1 of the node N1 starts to increase).

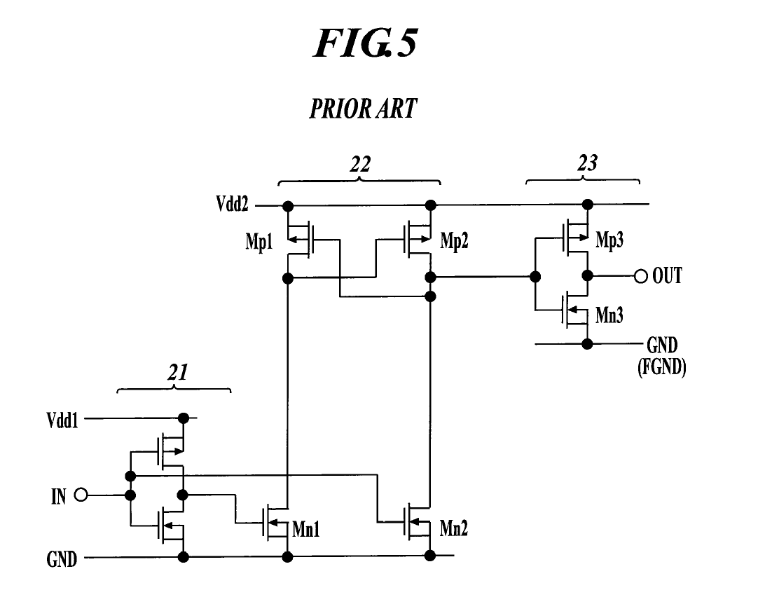

In this case, when the P-channel MOS transistors Mp4 and Mp5 in the middle stage are not present as in the conventional level shift circuit illustrated in FIG. 5, the potential Vn2 of the node N2 decreases up to the low level (GND) from the high level (Vdd2) as illustrated by a broken line in FIG. 3.

On the other hand, in the level shift circuit according to the present embodiment, the P-channel MOS transistor Mp5 is connected between the P-channel MOS transistor Mpg and the N-channel MOS transistor Mn2. Therefore, when the potential Vn2 of the node N2 decreases up to a potential (FGND+Vthp) which is higher than that of the floating ground FGND by a threshold voltage Vthp of the Mp5, the P-channel MOS transistor Mp5 is turned off, so that the potential Vn2 of the node N2 does not become FGND+Vthp or less.

Accordingly, when the Vdd2-FGND voltage is not more than the withstand voltage of the P-channel MOS transistors Mp1 and Mp3, gate insulating films of the Mp1 and the Mp3 are not destroyed. Similarly, when the FGND-GND voltage is not more than the withstand voltage of the P-channel MOS transistor Mp5, a gate insulating film of the Mp5 is not destroyed.

Next, when the input signal IN is changed from the high level (Vdd1) to the low level (GND), the N-channel MOS transistor Mn1 is changed from the off-state to the on-state, while the Mn2 is changed from the on-state to the off-state. Therefore, the potential Vn1 of the node N1 starts to decrease from the high level (Vdd2) to the low level (GND). The potential Vn2 of the node N2 starts to increase from the (FGND+Vthp) to the Vdd2.

When the potential Vn1 of the node N1 decreases up to a potential (FGND+Vthp) which is higher than that of the floating ground FGND by the threshold voltage Vthp of the Mp4, the P-channel MOS transistor Mp4 is turned off. Accordingly, the potential Vn1 of the node N1 does not become FGND+Vthp or less.

Accordingly, when the Vdd2-FGND voltage is not more than the withstand voltage of the P-channel MOS transistor Mp2, a gate insulating film of the Mp2 is not destroyed. Similarly, when the FGND-GND voltage is not more than the withstand voltage of the P-channel MOS transistor Mp4, a gate insulating film of the Mp4 is not destroyed.

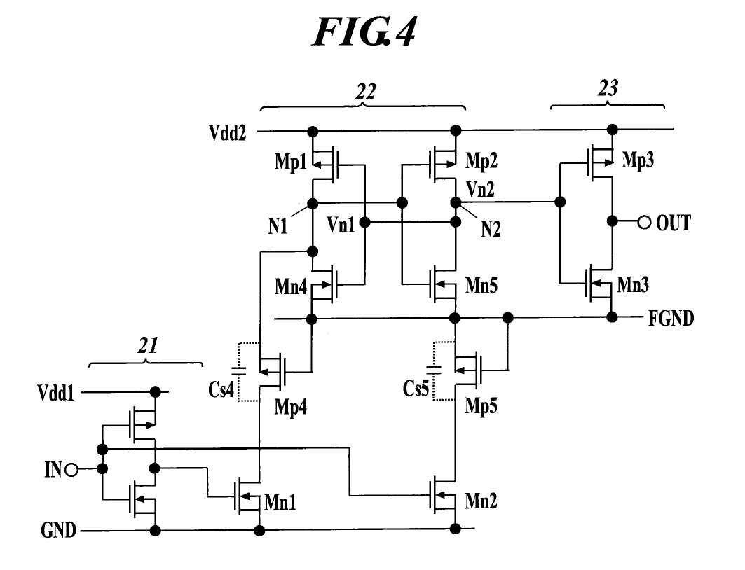

FIG. 4 illustrates a level shift circuit according to a second embodiment of the present invention.

In the level shift circuit according to the first embodiment illustrated in FIG. 2, the sizes of the MOS transistors Mp4 and Mp5 have to be increased to a certain degree in order to allow the Mp4 and Mp5 to have a withstand voltage. However, if the sizes of the Mp4 and Mp5 are increased, parasitic capacitances Cs4 and Cs5 between a source and a drain would also increase. If the parasitic capacitances Cs4 and Cs5 increase, a change of the drain voltage of the Mn1 and Mn2 would be transmitted to the nodes N1 and N2 via the parasitic capacitances when the N-channel MOS transistor Mn1 or Mn2 is turned on. As a result, the potentials Vn1 and Vn2 of the nodes N1 and N2 would be decreased, and the voltage not less than the withstand voltage would be applied to the P-channel MOS transistors Mp1 to Mp3, which might destroy the gate insulating films.

In the level shift circuit according to the second embodiment, an N-channel MOS transistor Mn4 is connected between the node N1 and the floating ground FGND, or an N-channel MOS transistor Mn5 is connected between the node N2 and the floating ground FGND, as illustrated in FIG. 4. The potential Vn2 of the node N2, which is the same as the gate voltage of the Mp1, is applied to the gate terminal of the Mn4 in order to turn on or off the Mn4 in a complementary manner with the Mp1, while the potential Vn1 of the node N1, which is the same as the gate voltage of the Mp2, is applied to the gate terminal of the Mn5 in order to turn on or off the Mn5 in a complementary manner with the Mp2.

In the present embodiment, when the potential Vn2 of the node N2 is decreased, the Mp1 is turned on, so that the potential Vn1 of the node N1 becomes Vdd2. Therefore, the N-channel MOS transistor Mn5, which is newly added, is turned on, so that the potential Vn2 of the node N2 can be made equal to that of the floating ground FGND. This structure can avoid the situation in which the potential Vn2 of the node N2 is decreased, since the change of the drain voltage of the N-channel MOS transistor Mn2 is transmitted to the node N2 via the parasitic capacitance Cs5 between the source and drain of the Mp5. Specifically, this structure can prevent the voltage not less than the withstand voltage from being applied to the Mp1 to Mp3.

Similarly, when the potential Vn1 of the node N1 is decreased, the Mpg is turned on, so that the potential Vn2 of the node N2 becomes Vdd2. Therefore, the N-channel MOS transistor Mn4, which is newly added, is turned on, whereby the potential Vn1 of the node N1 is made equal to that of the floating ground FGND. Accordingly, this structure can avoid the situation in which the potential Vn1 of the node N1 is decreased, since the change of the drain voltage of the N-channel MOS transistor Mn1 is transmitted to the node N1 via the parasitic capacitance Cs4 between the source and drain of the Mp4.

Although the invention made by the present inventors has been described above specifically based on the embodiments, the present invention is not limited to the embodiments. For example, the level shift circuit according to the above-mentioned embodiments uses the CMOS inverter as the input stage. However, the input stage is not limited to the CMOS inverter, and may be a differential amplifier circuit. Alternatively, the input stage may not be provided depending upon the circuit structure of the former stage.

In the above description, the present invention is applied to a level shift circuit of a voltage step down DC-DC converter. However, the present invention is not limited thereto. The present invention can be applied to a level shift circuit of a voltage step up DC-DC converter or an inverting DC-DC converter which generates a negative voltage.

The level shift circuit according to the present invention is not limited to the switching drive circuit in the DC-DC converter of the switching-regulator type, but can be applied to a unit which transmits a logical signal between circuits, each having a different ground level or different power supply voltage potential.

As described above, according to the present embodiments, there is provided a level shift circuit including: a level changing unit which includes a first conductive type MOS transistor and a second conductive type MOS transistor connected to each other in series between a first power supply voltage terminal to which a first power supply voltage is applied and a grounding point, and which unit receives a signal having a first amplitude which varies between a second voltage lower than the first power supply voltage and a ground potential to convert the received signal to a signal having a second amplitude with the first power supply voltage being defined as a reference; and an output stage which includes a first conductive type MOS transistor and a second conductive type MOS transistor connected to each other in series between the first power supply voltage terminal and a third voltage terminal to which a third voltage lower than the first power supply voltage and higher than the ground potential is supplied, and which stage is connected to an output node of the level changing unit, wherein a first conductive type MOS transistor whose gate terminal is connected to the third voltage terminal is connected in series between the first conductive type MOS transistor and the second conductive type MOS transistor of the level changing unit.

With this structure, when the potential of the output node of the level changing unit decreases up to near the voltage of the third voltage terminal, the first conductive type MOS transistor whose gate terminal is connected to the third voltage terminal is turned off. This structure can prevent the voltage not less than the withstand voltage from being applied to the first conductive type MOS transistor which constitutes the level changing unit and the CMOS inverter of the output stage.

Preferably, the level changing unit is a latch circuit which includes a first inverter circuit having a P-channel MOS transistor and an N-channel MOS transistor connected to each other in series between the first power supply voltage terminal and the grounding point, and a second inverter circuit having a P-channel MOS transistor and an N-channel MOS transistor connected to each other in series between the first power supply voltage terminal and the grounding point, and in which circuit an output node of each of the first and second inverter circuits is cross-linked to a gate terminal of the P-channel MOS transistors of the other inverter circuit. The output stage is a CMOS inverter which has a P-channel MOS transistor and an N-channel MOS transistor connected to each other in series between the first power supply voltage terminal and the third voltage terminal. A P-channel MOS transistor whose gate terminal is connected to the third voltage terminal is connected in series between the P-channel MOS transistor and the N-channel MOS transistor of each of the first and second inverter circuits.

With this structure, when the potential of the output node, which is one of the output nodes having lower potential, of the latch circuit decreases up to near the voltage of the third voltage terminal, the P-channel MOS transistor whose gate terminal is connected to the third voltage terminal is turned off. This structure can prevent the voltage not less than the withstand voltage from being applied to the P-channel MOS transistor which constitutes the latch circuit and the CMOS inverter of the output stage. Since the level changing unit is composed of a flip-flop latch circuit, a response of the output signal to the change in the input signal is increased.

Preferably, an N-channel MOS transistor is connected between the first power supply voltage terminal and the third power supply voltage terminal so as to be in series with each of the P-channel MOS transistors of the first and the second inverter circuits, to a gate terminal of which N-channel MOS transistor a voltage same as a gate voltage of a corresponding transistor out of the P-channel MOS transistors is applied.

This structure prevents the significant decrease in the potential of the output node of the CMOS inverter, which constitutes the latch circuit, through the parasitic capacitance between the source and the drain of the MOS transistor, the capacitance being provided in order to attain a high withstand voltage. This structure can prevent the voltage not less than the withstand voltage from being applied to the P-channel MOS transistor which constitutes the latch circuit and the CMOS inverter of the output stage.

Moreover, there is provided a switching power supply device which outputs a voltage having a potential different from a potential of an input voltage, the device including: an inductor connected between a voltage input terminal to which a direct-current voltage is input and an output terminal to which a load is connected; a drive switching element which intermittently flows an electric current through the inductor; a switching control circuit which generates a drive pulse with a constant pulse width and a frequency varying according to a feedback voltage from an output side, or a drive pulse with a constant frequency and a pulse width varying according to the feedback voltage, and generates a control signal for controlling the drive switching element to be turned on or off; and a driver circuit which turns on or off the drive switching element according to the control signal. The drive switching element is composed of an N-channel MOS transistor. A level shift circuit having the above configuration by which the control signal is level-shifted and supplied to the driver circuit is provided between the switching control circuit and the driver circuit.

With this structure, when the N-channel MOS transistor is used as the drive switching element for flowing an electric current through the inductor, the drive switching element can be brought into a sufficient on-state by a signal which is level-shifted by the level shift circuit, and the application of the voltage not less than the withstand voltage to the MOS transistor constituting the level shift circuit can be avoided.

Preferably, the third voltage terminal is a terminal to which one of terminals of the inductor is connected, and a capacitor is connected between the terminal and the power supply voltage terminal which supplies the first power supply voltage to the output stage of the level shift circuit and the driver circuit.

With this structure, the power supply voltage supplied to the output stage of the level shift circuit and the driver circuit is changed with the voltage of one of the terminals of the inductor, whereby the voltage of not less than a predetermined potential difference is prevented from being applied to the output stage of the level shift circuit and the driver circuit.

The present invention provides an effect that a level shift circuit having high withstand voltage from the viewpoint of a circuit can be realized without using a process for attaining a high withstand voltage.

The entire disclosure of Japanese Patent Application No. 2010-284005 filed on Dec. 21, 2010, including specification, claims, drawings and abstract are incorporated herein by reference in its entirety.

What is claimed is:

1. A level shift circuit comprising:
a level changing unit which includes a first conductive type MOS transistor and a second conductive type MOS transistor connected to each other in series between a first power supply voltage terminal to which a first power supply voltage is applied and a grounding point, and which unit receives a signal having a first amplitude which varies between a second voltage lower than the first power supply voltage and a ground potential to convert the received signal to a signal having a second amplitude with the first power supply voltage being defined as a reference; and
an output stage which includes a first conductive type MOS transistor and a second conductive type MOS transistor connected to each other in series between the first power supply voltage terminal and a third voltage terminal to which a third voltage lower than the first power supply voltage and higher than the ground potential is supplied, and which stage is connected to an output node of the level changing unit,
wherein a first conductive type MOS transistor whose gate terminal is connected to the third voltage terminal is connected in series between the first conductive type MOS transistor and the second conductive type MOS transistor of the level changing unit.

2. The level shift circuit according to claim 1,
wherein the level changing unit is a latch circuit which includes a first inverter circuit having a P-channel MOS transistor and an N-channel MOS transistor connected to each other in series between the first power supply voltage terminal and the grounding point, and a second inverter circuit having a P-channel MOS transistor and an N-channel MOS transistor connected to each other in series between the first power supply voltage terminal and the grounding point, and in which circuit an output node of each of the first and second inverter circuits is cross-linked to a gate terminal of the P-channel MOS transistors of the other inverter circuit,
wherein the output stage is a CMOS inverter which has a P-channel MOS transistor and an N-channel MOS transistor connected to each other in series between the first power supply voltage terminal and the third voltage terminal, and
wherein a P-channel MOS transistor whose gate terminal is connected to the third voltage terminal is connected in series between the P-channel MOS transistor and the N-channel MOS transistor of each of the first and second inverter circuits.

3. The level shift circuit according to claim 2, wherein an N-channel MOS transistor is connected between the first power supply voltage terminal and the third power supply voltage terminal so as to be in series with each of the P-channel MOS transistors of the first and the second inverter circuits, to a gate terminal of which N-channel MOS transistor a voltage same as a gate voltage of a corresponding transistor out of the P-channel MOS transistors is applied.

4. A switching power supply device which outputs a voltage having a potential different from a potential of an input voltage, the device comprising:
an inductor connected between a voltage input terminal to which a direct-current voltage is input and an output terminal to which a load is connected;
a drive switching element which intermittently flows an electric current through the inductor;
a switching control circuit which generates a drive pulse with a constant pulse width and a frequency varying according to a feedback voltage from an output side, or a drive pulse with a constant frequency and a pulse width varying according to the feedback voltage, and generates a control signal for controlling the drive switching element to be turned on or off; and
a driver circuit which turns on or off the drive switching element according to the control signal,
wherein the drive switching element is composed of an N-channel MOS transistor, and
wherein a level shift circuit having a configuration according to claim 2 by which the control signal is level-shifted and supplied to the driver circuit is provided between the switching control circuit and the driver circuit.

5. The switching power supply device according to claim 4, wherein the third voltage terminal is a terminal to which one of terminals of the inductor is connected, and a capacitor is connected between the terminal and the power supply voltage terminal which supplies the first power supply voltage to the output stage of the level shift circuit and the driver circuit.

6. A switching power supply device which outputs a voltage having a potential different from a potential of an input voltage, the device comprising:
an inductor connected between a voltage input terminal to which a direct-current voltage is input and an output terminal to which a load is connected;
a drive switching element which intermittently flows an electric current through the inductor;
a switching control circuit which generates a drive pulse with a constant pulse width and a frequency varying according to a feedback voltage from an output side, or a drive pulse with a constant frequency and a pulse width varying according to the feedback voltage, and generates a control signal for controlling the drive switching element to be turned on or off; and
a driver circuit which turns on or off the drive switching element according to the control signal,
wherein the drive switching element is composed of an N-channel MOS transistor, and
wherein a level shift circuit having a configuration according to claim 3 by which the control signal is level-shifted and supplied to the driver circuit is provided between the switching control circuit and the driver circuit.

7. The switching power supply device according to claim 6, wherein the third voltage terminal is a terminal to which one of terminals of the inductor is connected, and a capacitor is connected between the terminal and the power supply voltage terminal which supplies the first power supply voltage to the output stage of the level shift circuit and the driver circuit.
